(19) United States
(12) Patent Application Publication
(10) Pub. No.: US 2009/0212381 A1
(43) Pub. Date: Aug. 27, 2009

(54) WAFER LEVEL PACKAGES FOR REAR-FACE ILLUMINATED SOLID STATE IMAGE SENSORS

(75) Inventors: Richard Dewitt Crisp, Hornitos, CA (US); Belgacem Haba, Saratoga, CA (US); Vage Oganesian, Palo Alto, CA (US)

Correspondence Address: TESSERA;LERNER DAVID et al., 600 SOUTH AVENUE WEST, WESTFIELD, NJ, 07090, US

(73) Assignee: TESSERA, INC., San Jose, CA (US)

(21) Appl. No.: 12/393,233

(22) Filed: Feb. 26, 2009

Related U.S. Application Data
(60) Provisional application No. 61/067,209, filed on Feb. 26, 2008.

(51) Int. Cl. H01L 31/02; H01L 21/50

(52) U.S. Cl. 257/432; 438/65; 257/433; 257/E21.499; 257/E31.11

(57) ABSTRACT

A solid state image sensor includes a microelectronic element having a front face and a rear face remote from the front face, the rear face having a recess extending towards the front surface. A plurality of light sensing elements may be disposed adjacent to the front face so as to receive light through the part of the rear face within the recess. A solid state image sensor can include a microelectronic element having a front face and a rear face remote from the front face, a plurality of light sensing elements disposed adjacent to the front face, the light sensing elements being arranged to receive light through the rear face. Electrically conductive package contacts may directly overlie the light sensing elements and the front face and be connected to chip contacts at the front face through openings in an insulating packaging layer overlying the front face.

### CROSS-REFERENCE TO RELATED APPLICATIONS

This application claims the benefit of the filing date of U.S. Provisional Patent Application No. 61/067,209 filed Feb. 26, 2008, the disclosure of which is hereby incorporated herein by reference.

### BACKGROUND OF THE INVENTION

The subject matter shown and described in the present application relates to microelectronic image sensors and methods of fabricating, e.g., microelectronic image sensors.

Solid state image sensors, e.g. charge-coupled devices, (“CCD”) arrays, have a myriad of applications. For instance, they may be used to capture images in digital cameras, camcorders, cameras of cell phones and the like. One or more light-sensing elements on a chip, along with the necessary electronics are used to capture a “pixel” or a picture element, a basic unit of an image.

Improvements can be made to the structure of solid state image sensors and the processes used to fabricate them.

### SUMMARY OF THE INVENTION

In accordance with one embodiment, a solid state image sensor can include a microelectronic element having a front face and a rear face remote from the front face. The rear face may have an inner surface a first distance from the front surface in a direction normal to the front surface, an outer surface a second distance from the front surface in the normal direction and a recess that extends towards the front surface from the outer surface to the inner surface. A plurality of light sensing elements may be disposed adjacent to the front face aligned with the inner surface of the recess so as to receive light through the inner surface.

In accordance with one embodiment, a solid state image sensor can include a microelectronic element having a front face, a plurality of chip contacts at the front face, and a rear face remote from the front face. A plurality of light sensing elements can be disposed adjacent to the front face, and may be conductively connected with the chip contacts. The light sensing elements may be arranged to receive light through the rear face. An insulating packaging layer can overlie the front face and the light sensing elements. Electrically conductive package contacts can directly overlie the front face and the light sensing elements. Conductors can extend within openings in the packaging layer from the chip contacts to the package contacts.

The light sensing elements can include active semiconductor devices disposed adjacent to the front face. The conductors can include vertical interconnects in conductive communication with the active semiconductor devices and the package contacts.

In one embodiment, chip contacts can be exposed within the openings. The image sensor may include leads extending along interior surfaces of the openings which conductively connect the chip contacts with the package contacts. Each lead may cover an entire exposed interior surface of each opening or less than an entire exposed interior surface of each opening.

In one embodiment, each lead may extend along only a portion of an interior wall of each opening. For example, a second portion of the wall of the vertical interconnect remote from the first portion can remain uncovered by the lead.

In one embodiment, the light sensing elements can be disposed in a first region of the microelectronic element and the chip contacts can be disposed in a second region laterally adjacent to the first region, wherein the leads extend from the chip contacts to locations overlying the first region. The second region can be disposed between the first region and an edge of the microelectronic element.

The package contacts may be spaced farther apart than the chip contacts. The chip contacts may be disposed in at least a first direction along the front surface. The chip contacts may have a first pitch in the first direction and the package contacts may have a second pitch in the first direction. In one embodiment, the second pitch can be substantially greater than the first pitch.

In a particular embodiment, the package contacts can include one or the other of conductive masses and lands, or both. In such embodiment, the lands may be wettable by a fusible metal.

The image sensor may include a cover slip adjacent to the rear face. The image sensor may include an integrated stack lens disposed adjacent to the rear face.

In yet another embodiment of the present invention, a method of packaging a microelectronic image sensor includes (a) recessing portions of a rear surface of a device wafer, the portions being aligned with a plurality of light sensing elements adjacent to a front surface of the device wafer, (b) forming package contacts conductively interconnected with chip contacts exposed at the front surface, (c) assembling the device wafer with a light transmissive structure overlying the rear surface, and (d) severing the device wafer into individual packaged chips, each containing light sensing elements arranged to receive light through at least one of the recessed portions.

### BRIEF DESCRIPTION OF THE DRAWINGS

FIGS. 1A-1D illustrate a method of fabricating a rear-face illuminated image sensor, according to an embodiment of the present invention.

FIG. 2 is a schematic illustration of a cross section of a packaged back side illuminated image sensor according to the method illustrated in FIG. 1.

FIGS. 3A-3K illustrate a process for packaging rear face-illuminated image sensor dies according to another embodiment of the present invention.

FIG. 4 is a schematic illustration of a cross section of a packaged image sensor according to the method illustrated in FIGS. 3A-3K.

FIG. 5 is a top plan view of a packaged image sensor according to the method illustrated in FIGS. 3A-3K.

### DETAILED DESCRIPTION

In an embodiment of the present invention, a wafer level package assembly is disclosed having a backside illuminated image sensor. U.S. Pat. No. 6,646,289, which is hereby incorporated by reference, discloses integrated circuit devices employing a thin silicon substrate. Optronic components are formed on a surface facing away from a corresponding transparent protective layer.

As discussed in the '289 patent, the thinness of the silicon allows for the optronic components to be exposed to light impinging via the transparent protective layer. Color filters may be formed on an inner surface of the protective layer. Further, an array of microlenses may also be disposed on an inner surface of the protective layer.

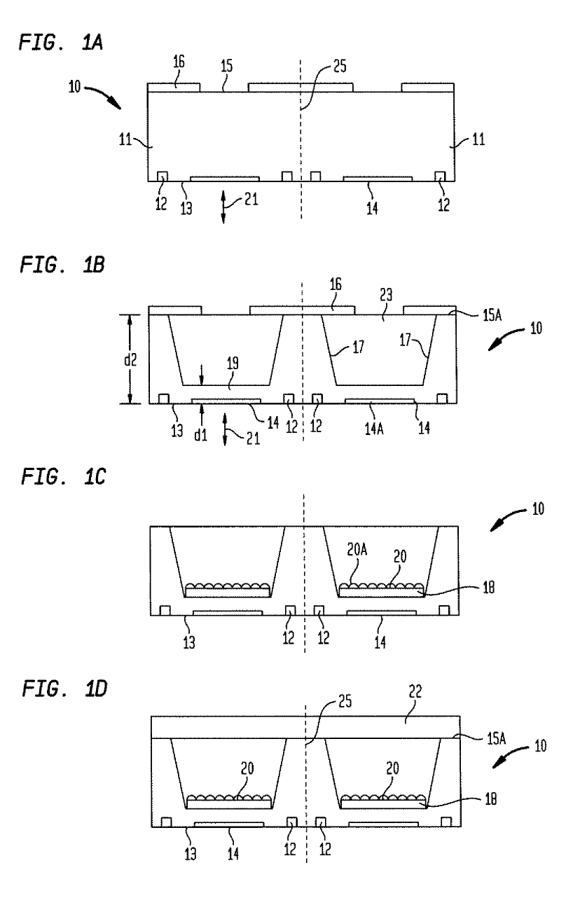

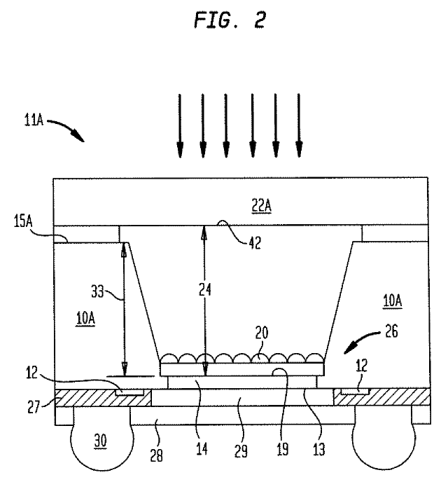

A method of fabricating a rear-face illuminated image sensor will now be described with reference to sectional views illustrating respective stages of fabrication in FIGS. 1A through 2. As illustrated in FIG. 1A, in a preliminary stage of fabrication, a device wafer 10 is shown with two adjoining regions 11 therein. A dicing lane 25 separates the regions 11, the dicing lane being the location along which the regions will be severed from each other at a later stage of fabrication. The device wafer 10 includes an active semiconductor layer or region which can consist essentially of silicon. Alternatively, the wafer may include other semiconductor materials such as for example, germanium (Ge), carbon (C), alloys or combinations of silicon with such material or one or more III-V compound semiconductor materials, each being a compound of a Group III element with a Group V element of the periodic table. Each region of the wafer has a front surface 13 at which bond pads 12 are exposed. Each region 11 typically includes one or more die attached to other such regions 11 at dicing lanes 25. Each region 11 includes an image sensor 14 adjacent to the front surface 13, the image sensor including a plurality of light-sensing elements typically arranged in an array for capturing an image cast thereon via light in directions 21 normal to the front surface.

Photolithography may be used to form mask patterns 16 overlying a rear surface 15 of the wafer, after which the wafer 10 may be etched from a rear surface 15 thereof using wet or dry etching as desired, as shown in FIG. 1B. Such etching forms recesses 23 in the rear surface 15 which extend inwardly from an outer surface 15A to an inner surface 19. The outer surface 15A is disposed at a greater distance (d2) from the front surface than the distance (d1) between the inner surface 19 and the front surface 13. The inner surface 19 is disposed at a distance d1 in a normal direction 21 to the front surface which is relatively close, i.e., at a distance which can range from a few microns up to about 20 microns. Thus, the thickness of the wafer 10 at the inner surface is defined by the distance d1. In an embodiment in which the device wafer 10 consists essentially of silicon, the distance between the front surface 13 and the inner surface 19 is necessarily small. The imaging light which strikes the light sensing elements 14A of the image sensor 14 passes through the inner surface 19 before interacting with the light sensing elements 14A within the thickness d1 of the wafer.

In addition, the transmissivity of the semiconductor material to light, especially silicon, can be limited. The distance d2 can be the same as the maximum thickness of the wafer in the normal direction 21. In an exemplary embodiment, the distance d2 and the maximum thickness of the device wafer 10 can range from about 50 microns to several hundred microns.

An anti-reflective coating (not specifically shown in FIG. 1B) may then be formed which overlies at least the inner surface 19 of the wafer within the recesses 23. The anti-reflective coating can help reduce the amount of light reflected back from the inner surface of the wafer and improve contrast ratio. Color filters 18 may then be formed or laminated to the wafer 10 to overlie the inner surface 19 within the recesses 23, as shown in FIG. 1C. The color filters 18 can be used to separate wavelengths of light arriving thereto through the color filters towards the inner surface 19 into different ranges of wavelengths that correspond to different ranges of color. Through use of a variety of different color filters each aligned with particular light-sensing elements of the image sensor, each color filter and light-sensing element can be used to sense only a limited predefined range of wavelengths corresponding to a particular range of colors. In such way, an array of undifferentiated light-sensing elements can be used with an appropriate combination of color filters geared to transmitting different colors to permit many different combinations of colors to be detected.

Sets of microlenses 20 may then be formed which overlie an exposed surface of the array of color filters 28. The microlenses 20 include tiny bumps of refractive material arranged in an array which help to focus light on one or more picture elements (“pixels”) of the imaging sensor. Each pixel typically is defined by an array of light-sensing elements, such that the light which arrives at the exposed surface 20A of each microlens is directed primarily onto one or more corresponding pixels.

As further illustrated in FIG. 1D, the inner surfaces 19 of the wafer 10 with the filters and microlenses thereon may be encapsulated by a lid wafer 22 as shown in FIG. 1D. The lid wafer 22 is at least partially transmissive to wavelengths of interest to the light-sensing elements incorporated in the image sensor. Thus, the lid wafer 22 may be transparent at such wavelengths, such as, for example, a lid wafer which consists essentially of one more various types of glass, or the lid wafer 22 may be transmissive with respect to only some wavelengths. Thus, the lid wafer 22 may include inorganic or organic materials, or a combination thereof.

After mounting the lid wafer 22 to the device wafer 10, the wafer may then be severed along the dicing lanes 25 into individual regions or dies 10A (FIG. 2) to form individually packaged dies 11A each having a lid 22A attached to a rear surface of an individual die 10A thereof. For example, the assembly including the lid wafer 22 and the device wafer 10 can be severed by sawing through the lid wafer 22 and the device wafer 10 or the assembly can be severed by sawing the lid wafer 22 and scribing and breaking the device wafer 10 along the dicing lanes 25.

In an alternative embodiment, the device wafer 10 is not assembled with an intact lid wafer 22 in a wafer level assembly process. Rather, individual lids 22A can be mounted to the outer surfaces 15A of individual regions 11 of the intact device wafer 10, such as via pick-and-place techniques. Then, the device wafer 10 with the individual lids mounted thereon is severed into individual chips, each having an attached lid. In another alternative embodiment, an individual lid 22A can be mounted to an individual die 10A after the device wafer 10 has been singulated into individual dies.

As also illustrated in FIG. 2, processing is performed at the front surface 13 of the die 10A in forming the packaged die 11A while the die remains attached to the device wafer. In an exemplary embodiment, bond pad extensions 27 are formed which extend along the front surface 13 in a lateral direction outward from original contacts 12, e.g., from the bond pads of the die 10A. The bond pads can be formed, for example, by selectively electroplating a metal onto a metal pattern defined previously, such as via sputtering or electroless plating and photolithography. Dielectric regions 29 may be disposed between the bond pad extensions, as illustrated in FIG. 2. The bond pad extensions 27 can include multiple features such as traces and interconnection pads which serve as contacts for the packaged die 11A.

Solder bumps 30 or other raised conductive features can be formed which extend from the bond pad extensions 27 in a direction downwardly away from the front surface 13. For example, the conductive features can include solder balls 30 attached to the extensions 27 in form of a ball grid array (“BGA”) or other arrangement. A solder mask or other dielectric layer 28 overlying the front surface 13 can avoid solder or other fusible metal used to mount the packaged die 11A from flowing in directions along the front surface of the packaged die 11A. The dielectric layer 28 may form a layer which encapsulates the original contacts 12 and the image sensor 14 at the front surface 13.

It is to be noted that, in one embodiment, the above-described packaging processes (FIG. 2) performed relative to the front surface 13 of the die can be performed prior to severing the assembly into individual packaged dies. In a particular embodiment, the above-described processes (FIG. 2) can be performed prior to some or all of the process steps described above with respect to FIGS. 1A through 1D.

FIG. 2 is a schematic illustration of a cross section of a packaged back side illuminated image sensor according to the method illustrated in FIG. 1. Here, a pixel 26 is illustrated adjacent the image sensor 14. Also the packaged sensor is shown coupled to a dielectric 28 and a BGA 30. Further, this figure illustrates profiled silicon etching from the backside of the wafer. The glass wafer 22 can be provided on a wafer level prior to the dicing step as previously mentioned. The dielectric 28 can also be provided on a wafer level prior to the dicing step to singulate the dies.

The rear face illuminated configuration of the packaged die 11A achieves a standoff height 24 between the image sensor 14 and the inner surface 42 of the lid 22A. As seen in FIG. 2, the standoff height 24 includes a portion of the thickness of the die. Specifically, the standoff height 24 includes a thickness 33 of the die between the outer surface 15A and the inner surface 19. An advantageous arrangement is achieved because the standoff height 24 is provided in the same direction as the thickness of the die 10A, rather than being in addition to the die thickness as it is in packages with lids mounted above the front surface. As a result, greater standoff height can be achieved than in some conventional front-face illuminated dies in which the total thickness of the package is limited, a result which may lead to improvements in cost, processing or the thickness of the package.

Another advantage is that the foregoing-described processes for forming packaged dies can be performed without requiring a handler wafer to be mounted to the device wafer during such processing. Still another advantage is that, with the recesses being made in the rear surface in alignment with the image sensors, processes such as grinding or polishing may not need to be performed to reduce the total thickness of the device wafer 10. Still another advantage is the ability to use wafer-level chip-scale packaging technology to form the packaged dies by the above-described processes.

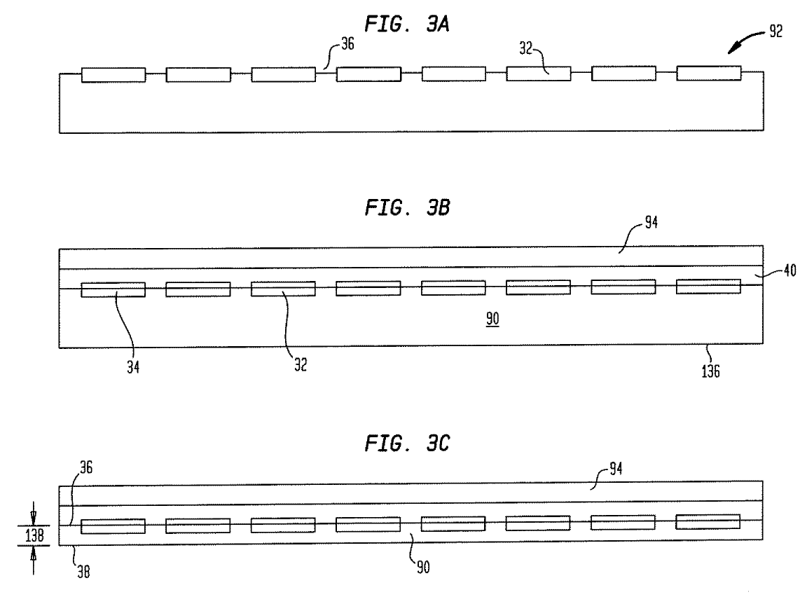

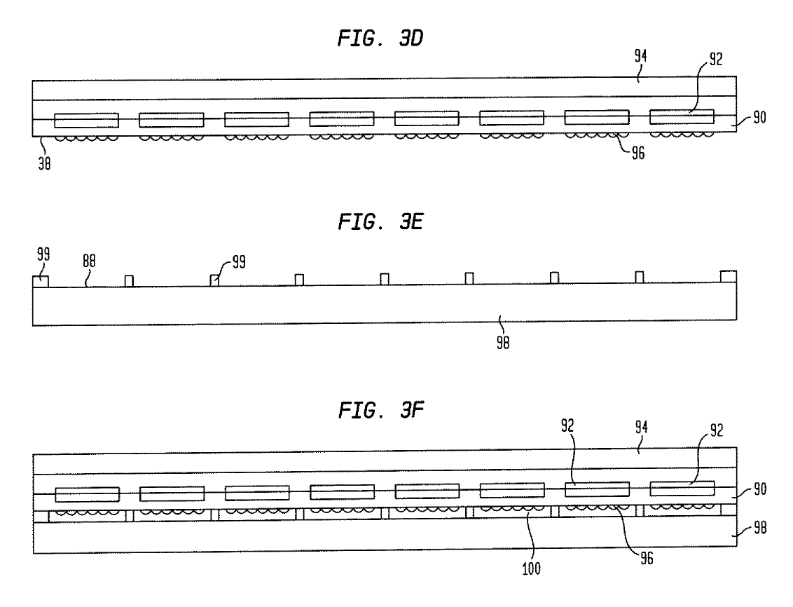

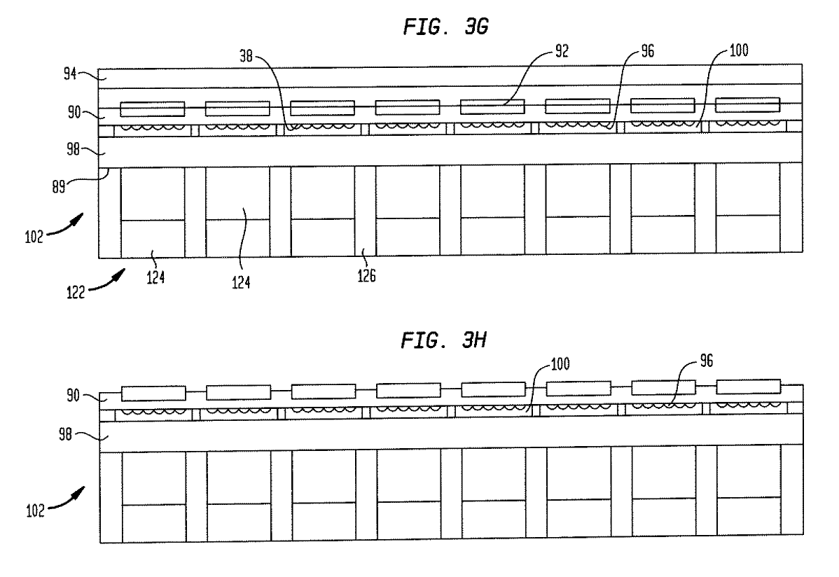

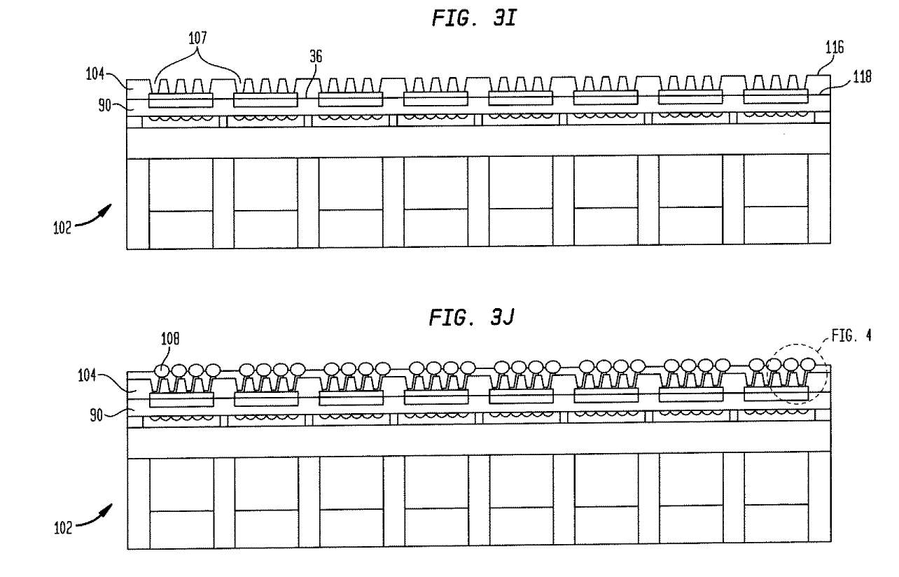

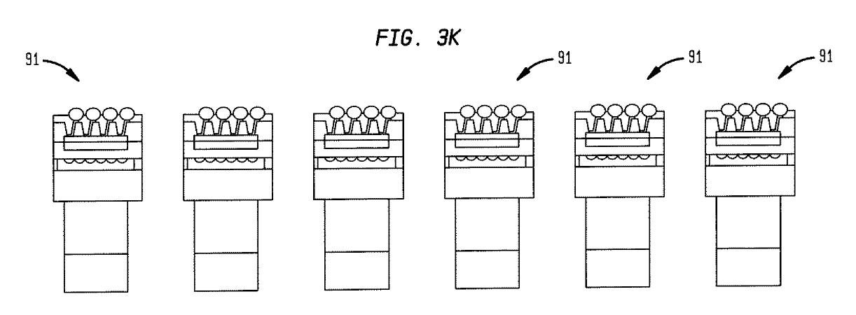

Referring to FIG. 3A, a process will now be described of packaging rear face-illuminated image sensor dies according to another embodiment of the present invention. As seen in FIG. 3A, a device wafer 90 includes active semiconductor devices including light-sensing elements 32 and other active semiconductor devices (not shown) disposed adjacent to a front face 36 of the wafer 90.

A temporary carrier, e.g., a handler wafer 94 is laminated onto the device wafer 90, as shown in FIG. 3B. It is important that during fabrication, the wafer-level assembly has sufficient mechanical integrity to withstand further assembly steps. Typically, the carrier is relatively rigid in order to support the device wafer 90 against cracking or breaking during subsequent fabrication processes. As the support wafer serves no optical function, a variety of different materials may be used. For instance, silicon, tungsten or certain metal composite materials may be used. In one embodiment, a material is used which has a coefficient of thermal expansion similar to that of the semiconductor material, e.g., silicon, which is used to form the device wafer 90.

Thereafter, the device wafer 90 is thinned from a rear face 136 of the wafer until a desired thickness 138 is reached between the front face 36 and the rear face 38, as shown in FIG. 3C. As illustrated in FIG. 3C, the thickness of the device wafer 90 is reduced by grinding, polishing, etching or the like. In one embodiment, the thickness can be reduced to between about 5 microns and 20 microns. In one embodiment, the thickness can be reduced to less than 5 microns.

Color masks (not shown), e.g., sets of color filters as described above, microlenses 96, or both can be applied on the device wafer 90 at a rear surface 38 as shown in FIG. 3D. In one embodiment, the color masks, microlenses or both can be attached to the image sensor dies using an adhesive. Preferably, an adhesive can be used which is at least partially transparent to light of wavelengths of interest to the light-sensing elements of the image sensor. Forming an array of microlenses separately and then joining the microlenses to the device wafer via lamination can reduce stresses in the device wafer and lead to greater mechanical stability. An array of micro lenses may be formed as arrays at the die or wafer level, in or on a sheet of glass or organic polymer. Techniques to form an array include printing, stamping, etching, embossing and laser ablation. An array of micro lenses can be laminated with the device wafer 90 having the same dimension as the array. Such a lamination of the device wafer 90 and the array will provide mechanical support to the device wafer 90.

Next, a lid wafer or “coverslip” wafer 98 is prepared which has standoffs 99 thereon. The standoffs 99 may take the form of a patterned adhesive layer projecting from an inwardly directed inner surface 88 of the coverslip wafer, as shown in FIG. 3E. The standoffs 99 maintain the inner surface 88 at a desired spacing from the rear surface 38 of the device wafer 90. In such manner, a cavity 100 may be formed which lies between the inner surface 88 of the coverslip wafer 98 and the rear surface 38. The coverslip wafer 98 covers the microlenses 96 once it has been laminated with the device wafer 90 as shown in FIG. 3F. The coverslip wafer 98 can help avoid dust from contacting the microlenses 96. By laminating the coverslip wafer 98 onto the rear surface 38 of the device wafer 90 in one integral unit, the major surface of the coverslip wafer 98 is maintained parallel to the rear surface 38, an arrangement which benefits the focusing of light onto the light-sensing elements 92 of the image sensors at the front surface 36 of the device wafer 90.

Thereafter, as shown in FIG. 3G, a wafer-level integrated stacked lens assembly 102 is laminated to an outer surface 89 of the coverslip wafer 98. The stacked lens assembly 102 includes a plurality of individual lens stacks 122 which are attached together at edges 126. The individual lens stacks 122 may include one or more optical elements 124 having a refractive or diffractive property, or both, or which may have a reflective, absorptive, emissive or other optical property or a combination thereof. Each lens stack is aligned with at least one image sensor 92 of the device wafer so as to cast imaging light through the rear face 38 of the wafer onto the light-sensing elements of the image sensor.

FIG. 3H illustrates a further stage of processing after the handle wafer 94 or temporary carrier is removed. Next, as seen in FIG. 3I, a patterned dielectric layer 104, for example, a patterned layer of a polymeric material with an adhesive backing or simply, an adhesive dielectric layer 104 having holes 106 punched therein is laminated to the front surface 36 of the device wafer 90. The patterned dielectric layer 104, e.g., punched adhesive has openings or apertures, e.g., through holes 107 extending between top and bottom surfaces 116, 118 which are aligned with electrical contacts, e.g., bond pads, exposed at the front surface 36 of the dies of the wafer.

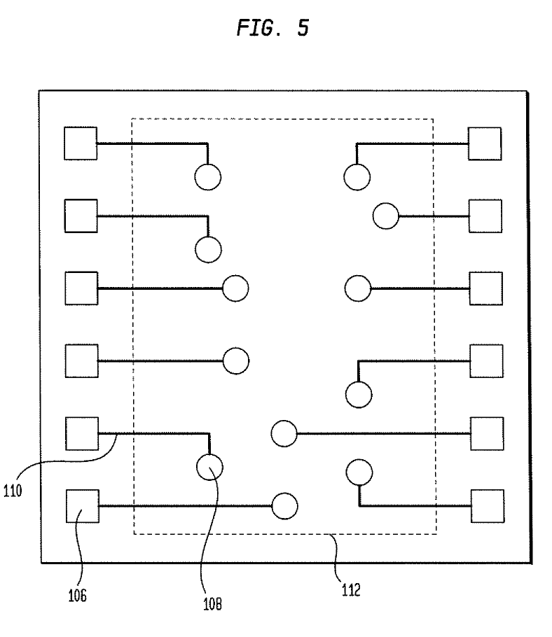

Thereafter, as seen in FIG. 3J, electrical contacts 108, exposed at the top surface 116 of the dielectric layer, may be formed which are conductively connected to the chip contacts at the front surface 36. Any manner of package contacts 108 may be formed, such as, for example, solder balls, stud bumps or a land grid array. In an embodiment of the present invention, the package contacts 108 can be distributed over the front surface of the die as illustrated in FIG. 5 such that the package contacts directly overlie at least some of the light-sensing elements of the image sensor. The assembly including the device wafer 90 may then be singulated into individual packaged chips, as shown in FIG. 3K.

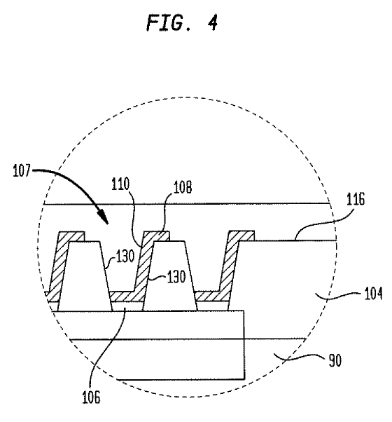

As best seen in FIG. 4, in one embodiment, the package contacts 108 exposed at the top or outer surface 116 of the dielectric layer 104 are formed integrally with connecting leads 110 by electroplating onto exposed contacts 106 within the through holes 107. To form such leads and contacts, a seed metal layer may first be deposited onto an exposed interior walls 130 of the holes and a top surface 116 of the dielectric layer, using electroless plating or sputtering. Thereafter, a patterned photoresist mask and subsequent removal of the exposed portions of the seed layer can be used to define the locations of the desired leads. Through this process, the seed layer will be cleared from portions of the walls 130. A 3-D lithography process may be employed, such as described in commonly owned U.S. Pat. No. 5,716,759 to Badehi, the disclosure of which is incorporated by reference herein, to form seed layer patterns which cover the bottom and one wall of the openings 106. The wafer-level assembly can then be contacted with an electroplating bath to plate leads 110 and pads 108 having a desired thickness onto the seed metal layer. More information regarding this process is provided in U.S. application Ser. No. 11/789,694, filed Apr. 25, 2007, and entitled, WAFER-LEVEL FABRICATION OF LIDDED CHIPS WITH ELECTRODEPOSITED DIELECTRIC COATING, which is also hereby incorporated by reference.

Alternatively, without requiring 3-D lithography, portions of the seed metal layer which overlie the top surface 116 of the dielectric layer can be patterned and the seed layer along entire walls of the through holes 107 can remain intact. In this way, the inner walls of the through holes are plated all around during the electroplating step.

In a particular embodiment of the invention, the dielectric layer 104 is not a pre-formed layer which is then laminated onto the wafer-level assembly. In such case, the dielectric 104 can be deposited using electrophoretic deposition spin-on, roller-coating or other deposition method.

Interconnections 110, which extend upward from the front surface of the chip and laterally along a surface of layer 104 connect the peripheral bonding pads or chip contacts 106 of each chip to an area array of package contacts 110. The package contacts, 110, which may include under bump metal (UBM) pads and solder bumps or balls, can be distributed over the front surface of the chip. Alternatively, package contacts can be in the form of conductive masses, lands or the like. The lands may be wettable by a fusible metal such as solder, tin or a eutectic composition including a fusible metal.

The dotted line in FIG. 5 marks a boundary enclosing an area of the array 112 of light-sensing elements 92 which make up an optically active portion of the image sensor of each chip. Thus, at least some of the package contacts may directly overlie the light-sensing elements of the image sensor. Stated another way, at least some of the package contacts 108 may be disposed at positions which are aligned with the light-sensing elements in a direction normal to the top surface 116 of the dielectric layer 104. The package contacts 108 can be used to connect each packaged die 91 to a circuit panel such as an application circuit board.

The above-discussed method of forming redistributed package contacts can improve the reliability by allowing the use of larger solder balls for robust interconnection and better thermal management of the device's input output (“I/O”) system.

Further, this type of structure is advantageous because chip contacts 106 are commonly placed very closely together. For instance, the pitch of the chip contacts is usually very small, whereas the pitch of the package contacts is normally substantially greater than the pitch of the chip contacts. Substantially greater can be defined such that the ratio of the pitch of the package contacts and the pitch of the chip contacts is greater than 1.2. The ratio may be much greater than 1.2 and 2.0. Redistribution also allows for package contacts 108 to be spaced further apart than chip contacts 106 and allows the package contacts to be larger in size.

Some or all of the methods and processes described in the foregoing may be performed via chip level packaging techniques with respect to individual chips as well as wafer level packaging techniques as described above. Further, the methods recited herein are applicable to solid state image sensors as well as other types of sensors.

In the foregoing description, terms such as “top”, “bottom”, “upward” or “upwardly” and “downward” or “downwardly” refer to the frame of reference of the microelectronic element, unit or circuit board. These terms do not refer to the normal gravitational frame of reference.

As used in this disclosure, a statement that an electrically conductive structure is “exposed at” a surface of a dielectric structure indicates that the electrically conductive structure is available for contact with a theoretical point moving in a direction perpendicular to the surface of the dielectric structure toward the surface of the dielectric structure from outside the dielectric structure. Thus, a terminal or other conductive structure which is exposed at a surface of a dielectric structure may project from such surface; may be flush with such surface; or may be recessed relative to such surface and exposed through a hole or depression in the dielectric.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A solid state image sensor, comprising:
a microelectronic element having a front face and a rear face remote from the front face, the rear face having an inner surface a first distance from the front surface in a direction normal to the front surface, an outer surface a second distance from the front surface in the normal direction and a recess that extends towards the front surface from the outer surface to the inner surface; and
a plurality of light sensing elements disposed adjacent to the front face aligned with the inner surface of the recess so as to receive light through the inner surface.

2. The image sensor as claimed in claim 1, further comprising an at least partially transparent lid disposed adjacent to the rear face, the lid overlying the recess.

3. The image sensor as claimed in claim 1, further comprising electrical contacts exposed at the front face, the contacts conductively connected to the light sensing elements.

4. A solid state image sensor, comprising:
a microelectronic element having a front face, a plurality of chip contacts at the front face, a rear face remote from the front face, and a plurality of light sensing elements disposed adjacent to the front face and conductively connected to the chip contacts, the light sensing elements being arranged to receive light through the rear face;
an insulating packaging layer overlying the front face and the light sensing elements;
electrically conductive package contacts directly overlying the front face and the light sensing elements; and
conductors extending within openings in the packaging layer from the chip contacts to the package contacts.

5. The image sensor as claimed in claim 4, wherein the light sensing elements include active semiconductor devices disposed adjacent to the front face.

6. The image sensor as claimed in claim 5, wherein the conductors include vertical interconnects in conductive communication with the active semiconductor devices and the package contacts.

7. The image sensor as claimed in claim 4, wherein the chip contacts are exposed within the openings, the image sensor further comprising leads extending along interior surfaces of the openings connecting the chip contacts to the package contacts, each lead covering less than an entire exposed interior surface of each opening.

8. The image sensor as claimed in claim 4, wherein each lead extends along only a portion of an interior wall of each opening.

9. The image sensor as claimed in claim 8, wherein a second portion of the wall of the vertical interconnect remote from the first portion remains uncovered by the lead.

10. The image sensor as claimed in claim 4, wherein the light sensing elements are disposed in a first region of the microelectronic element and the chip contacts are disposed in a second region laterally adjacent to the first region, wherein the leads extend from the chip contacts to locations overlying the first region.

11. The image sensor as claimed in claim 10, wherein the second region is disposed between the first region and an edge of the microelectronic element.

12. The image sensor as claimed in claim 4, wherein the package contacts are spaced farther apart than the chip contacts, and wherein the chip contacts are disposed in at least a first direction along the front surface, the chip contacts having a first pitch in the first direction and the package contacts having a second pitch in the first direction, the second pitch being substantially greater than the first pitch.

13. The image sensor as claimed in claim 4, wherein the package contacts include conductive masses.

14. The image sensor as claimed in claim 4, wherein the package contacts include lands.

15. The image sensor as claimed in claim 14, wherein the lands are wettable by a fusible metal.

16. The image sensor as claimed in claim 4, further comprising a cover slip adjacent to the rear face.

17. The image sensor as claimed in claim 4, further comprising an integrated stack lens disposed adjacent to the rear face.

18. A method of packaging a microelectronic image sensor comprising:
(a) recessing portions of a rear surface of a device wafer, the portions being aligned with a plurality of light sensing elements adjacent to a front surface of the device wafer;
(b) forming package contacts conductively interconnected with chip contacts exposed at the front surface;
(c) assembling the device wafer with a light transmissive structure overlying the rear surface; and
(d) severing the device wafer into individual packaged chips, each containing light sensing elements arranged to receive light through at least one of the recessed portions.

19. The method as claimed in claim 18, further comprising forming a plurality of microlenses within each recessed portion, each microlens aligned with one or more of the light sensing elements.

20. The method as claimed in claim 19, wherein step (c) includes assembling the device wafer with a lid wafer.

21. The method as claimed in claim 20, wherein step (d) includes severing the device wafer and the lid wafer.
